(19) United States
(12) Patent Application Publication
(10) Pub. No.: US 2024/0393063 A1
(43) Pub. Date: Nov. 28, 2024

(54) METHOD FOR PRODUCING A COOLING DEVICE

(71) Applicant: Miba Sinter Austria GmbH, Laakirchen (AT)

(72) Inventors: Manuel POHN, Lenzing (AT); Wolfgang SCHIMPL, Scharnstein (AT); Michael BUCHEGGER, Vorchdorf (AT)

(73) Assignee: Miba Sinter Austria GmbH, Laakirchen (AT)

(21) Appl. No.: 18/669,785

(22) Filed: May 21, 2024

(30) Foreign Application Priority Data
May 22, 2023 (AT) A50396/2023

(51) Int. Cl. F28F 3/04; F28F 3/02

(52) U.S. Cl. CPC F28F 3/04; F28F 3/022; F28F 2255/18

(57) ABSTRACT

A method for producing a cooling device includes the steps of providing a material and forming a cooling structure from the material, a sinter powder being used as the material, from which a green compact is produced by pressing, the green compact being sintered into a preform, and the cooling structure in the form of cooling elements being produced from the preform by forming, for which a part of the preform is pressed through a forming tool, and the cooling structure is calibrated after forming.

### CROSS REFERENCE TO RELATED APPLICATIONS

Applicant claims priority under 35 U.S.C. § 119 of Austrian Application No. A50396/2023 filed May 22, 2023, the disclosure of which is incorporated by reference.

### BACKGROUND OF THE INVENTION

### 1. Field of the Invention

The invention relates to a method for producing a cooling device, comprising the steps of providing a material and forming a cooling structure from the material.

The invention further relates to a cooling device for cooling components, comprising a base element having a first surface, and with a cooling structure having cooling elements, which is arranged on the base element so as to project beyond the first surface.

### 2. Description of the Related Art

What are known as power electronics components, such as power semiconductors, are sufficiently known from the prior art. Such components are often used in motor vehicles, for example. It is also known that these components generate large amounts of heat during operation, which often require the help of a cooling medium to dissipate. A wide variety of coolers for this purpose are known in the prior art.

For example, DE 11 2007 000 829 B4 describes an arrangement of an inverter and a cooler for cooling the inverter, the cooler comprising the following: a substrate having a surface on which the inverter is disposed, heat dissipation components attached to another opposite surface of the substrate and surrounding an area opposite an area in which the inverter is arranged on the one surface of the substrate, a main pipe remote from the other surface of the substrate and defining a space between the main pipe and the substrate, and which is configured to be fed with a coolant and to allow the coolant to contact the heat dissipation components; and a secondary pipe projecting from the main pipe toward the substrate and facing the region of the substrate in which the inverter is disposed so as to impinge on the other surface of the substrate at the region facing the region in which the inverter is disposed with a coolant fed to the main pipe, wherein the coolant supplied to the main pipe is separated from the coolant supplied to the area until it is expelled from the secondary pipe.

What are known as pin fin heat sinks have also been described in the prior art, which are flushed with a cooling medium and transfer the heat from the pins to the cooling medium in this manner. DE 10 2019 108 106 A1, for example, describes a cooler for a power semiconductor in an inverter, wherein the cooler is configured in two parts and comprises: a base plate as a first part, which can be connected to the power semiconductor in a thermally conductive manner, a heat sink as a second part, which is arranged on the base plate, wherein the heat sink has at least one undulating recess, which is formed continuously from a side of the heat sink facing away from the base plate to a side facing the heat sink, wherein the first and second parts are connected to one another and are coated by means of a layer that protects both parts from electrochemical reduction.

DE 10 2018 216 859 A1 discloses a device for cooling components, comprising: a first and a second base body, cylindrical and/or conical first cooling ribs, around which a coolant can flow, which are formed in the first base body, and cylindrical and/or conical second cooling ribs, around which the coolant can flow, which are formed in the second base body, the second cooling ribs being joined to the first base body in such a way that the second cooling ribs come to lie between the first cooling ribs without touching the first base body.

### SUMMARY OF THE INVENTION

The problem to be solved of the present invention is to more simply produce a cooling device for high-precision components or to provide such a cooling device.

The problem of the invention is solved by the method mentioned at the outset, according to which it is provided that a sintered powder is used as the material, from which a green compact is produced by pressing, that the green compact is sintered into a preform, and that the cooling structure in the form of cooling elements is produced from the preform by forming, for which a part of the preform is pressed through a forming tool and the cooling structure is calibrated after forming.

Furthermore, the problem of the invention is solved with the cooling device mentioned in the introduction, in which the base element and the cooling elements are composed of a sintered material and the cooling elements are produced from the material of the base element by forming and that at least some of the cooling elements in the head region have a higher density than the other cooling elements and/or that at least some of the cooling elements in the head region are a different shape to the other cooling elements.

The advantage thereof is that, as a result of forming the base element into the cooling elements and the subsequent calibration for the production thereof, no waste material is produced with higher component precision, as is the case in machining, for example. In addition, all cooling elements of the cooling device can be manufactured at the same time, thus achieving a corresponding increase in productivity. For forming, it is advantageous that the preform, though it already has corresponding strength due to sintering, can be formed more easily due to pores compared to a solid material. This advantage is also noticeable during calibration, as it makes calibration easier.

According to an embodiment of the invention, it can be provided that the cooling structure is formed at least in regions by calibration. It is thus possible not only to improve component precision in one step, but also to provide cooling elements that could otherwise only be produced with more complex forming.

According to another embodiment of the invention, it can be provided that the height of the cooling elements is adjusted during calibration by pressing material out of the head region of the cooling elements into a region adjacent to or below the head region of the cooling elements. Therefore, on the one hand, this achieves a simple possibility for height calibration of the cooling elements, by which a cooling structure with minor height variations of the cooling elements can be provided. On the other hand, undercut cooling elements can be produced more cost-effectively and without machining. In particular, at least some of the cooling elements can be mushroom shaped for this purpose; in order to influence the flow behavior in the region of the cooling structure. Using a sintered material is also advantageous for these undercut cooling element shape embodiments since this makes it easier to press the material in the head region of the cooling elements due to residual pores. The height of the cooling elements, in particular the same height of the cooling elements except for tolerances, can thus be adjusted easily and quickly without machining.

According to a further embodiment of the invention, it can be provided that the cooling structure is produced by using a perforated plate as a forming tool or a plurality of perforated plates as forming tools in the form of pin-shaped cooling elements. The forming tool can thus be configured in a relatively simple manner. In addition, it can easily be adapted to different cooling element shapes. Surprisingly, despite the large contact area, demolding the cooling elements by pulling off the perforated plate does not pose problems with regard to material chipping, etc.

It is also advantageous for the preform to be plate shaped in accordance with an embodiment of the invention, since forming the preform can be significantly simplified in this way. The plate shape also allows for easier forming through the use of a more simply configured forming tool.

According to a further embodiment of the invention, it can be provided that the preform is produced with different a thickness at least in sections. This enables improved “flow behavior” of the material for producing the cooling structure. In addition, differences in the height of the cooling elements, which they can have after forming, in particular using a perforated plate, can thus already be accounted for during production. In regions in which the cooling elements are formed higher during forming, the preform can have a smaller thickness in this way. Subsequently, the cooling elements can be produced with higher precision as early as during forming, so that the subsequent calibration can be carried out with less effort or lower calibration forces.

It has proven to be advantageous for the flow behavior of the material during forming if, according to one embodiment of the invention, the preform is produced thinner in edge sections than in a central section.

According to an embodiment of the invention, it can be provided that the preform is re-compressed and that the cooling structure is formed during the re-compression. By combining these steps into a single method step, the production time of the cooling device can be correspondingly shortened. It is advantageous that, due to the fact that the preform has not been re-compressed in advance, forming it into the cooling structure can be carried out more easily on account of a higher pore proportion.

According to another embodiment of the invention, the base element and the cooling elements can have a density of at least 98% of the full density of the material used, as a result of which the cooling device can have improved corrosion properties even without further post-treatment, despite powder metallurgical production. This is particularly advantageous for the cooling elements around which a coolant flows during operation.

According to another embodiment variant of the invention, it can be provided that the cooling elements have a height above the first surface of the base element between 2 mm and 20 mm. With regard to the formability, these heights of the cooling elements have proven to be advantageous, since the material flow over the entire height of the cooling elements can thus be made more uniform.

According to an embodiment of the invention, it can be provided that a rear side of the base element is configured with a flat surface, such that the contact of the base element on the one hand during forming against a punch and on the other hand against a component to be cooled can be improved during operation of the cooling device.

According to a further embodiment of the invention, it can be provided that at least one further structural element is arranged on the first surface of the base element, which protrudes beyond the cooling elements in the direction of the height, and which is produced in net-shape or near net-shape quality. The powder-metallurgical production of the cooling device is also advantageous in this case, since further planes can be produced on the cooling device without complex machining, as these are already taken into account in the original forming for the production of the preform.

### BRIEF DESCRIPTION OF THE DRAWINGS

Other objects and features of the invention will become apparent from the following detailed description considered in connection with the accompanying drawings. It is to be understood, however, that the drawings are designed as an illustration only and not as a definition of the limits of the invention.

In the drawings,

FIG. 1 shows a side view of a cooling device with a component to be cooled;

FIG. 2 shows an oblique view of a cooling device;

FIG. 3 shows an embodiment of a preform;

FIG. 4 shows an embodiment of a tool for producing the cooling device;

FIG. 5 shows an embodiment of the calibration step to produce the cooling device in side view; and

FIG. 6 shows a detail of a height-calibrated cooling device in side view.

### DETAILED DESCRIPTION OF PREFERRED EMBODIMENTS

It is worth noting here that the same parts have been given the same reference numerals or same component designations in the embodiments described differently, yet the disclosures contained throughout the entire description can be applied analogously to the same parts with the same reference numerals or the same component designations. The indications of position selected in the description, such as above, below, on the side etc. refer to the figure directly described and shown, and these indications of position can be applied in the same way to the new position should the position change.

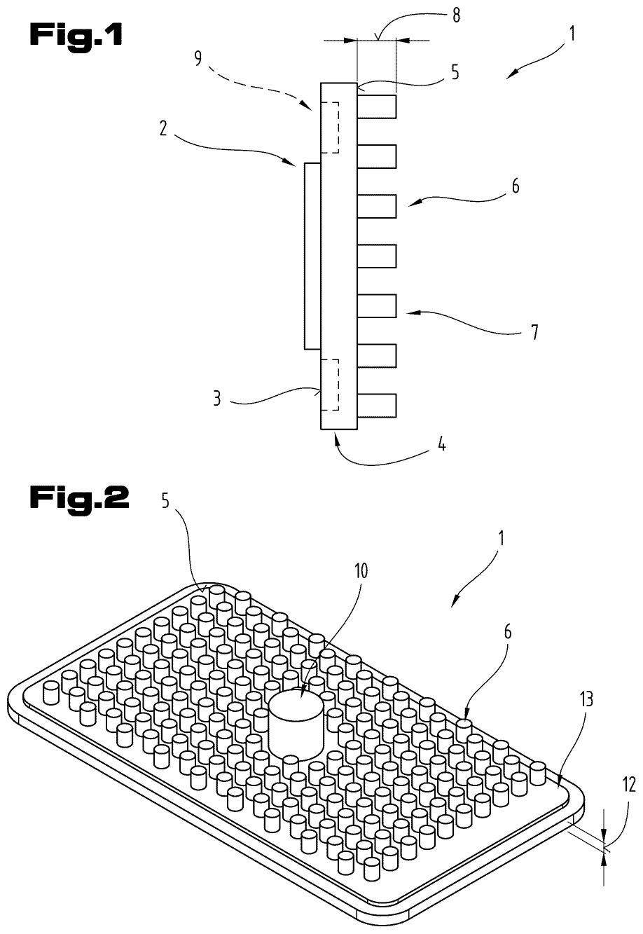

FIG. 1 shows a side view of a cooling device 1.

The cooling device 1 is used to cool a component 2 or a plurality of components 2 or an assembly. For this purpose, the cooling device 1 bears with a rear side 3 against the at least one component 2 in particular directly, i.e. is preferably in direct contact with the component 2 for heat exchange.

The component 2 is preferably an electronic component, in particular what is known as a power electronics component or high-power electronics component or a power semiconductor or high-power semiconductor but can also be configured differently. In particular, such components 2 or assemblies of/with these components 2 can be provided for power in the range from several kW to MW. Such components 2 are used for transforming electrical energy with switching electronic components, for example. Typical applications are converters or frequency converters in the field of electric drive technology, solar inverters and converters for wind turbines for feeding regeneratively generated energy or switched-mode power supplies into the grid, generally the conversion of AC voltage into DC voltage by rectifiers, the conversion of DC voltage into AC voltage by inverters, controllers, for example in the drive technology of an electric drive in electric vehicles or hybrid vehicles, battery management systems, etc. A power electronics component can be, for example, a semiconductor, in particular a what is known as a power semiconductor, e.g. an IGBT.

Since such components 2 are known from the relevant prior art per se, reference is made to this prior art to avoid repetition with regard to details.

The cooling device 1 comprises a base element 4, which also forms the rear side 3 of the cooling device 1 and which has a cooling structure on a first surface 5 or consists of the base element 4 and the cooling structure. The cooling structure is formed by cooling elements 6, which are arranged protruding beyond the first surface 5 on the base element 4 and are integrally connected thereto, as can also be seen from FIG. 2. In other words, in the preferred embodiment, the cooling device is formed by only a single part. Irrespective of the one-piece configuration, within the scope of the invention, it is possible for a plurality of cooling devices 2 to be combined with one another to form a cooling device group per component 2 or assembly composed of/with at least one such component 1 according to the invention. In particular, a plurality of cooling devices 1 can therefore also be assembled in modular fashion to form a cooling device group.

The base element 4 and the cooling elements 6 are made or are composed of a sintered material. Furthermore, the cooling elements 6 are produced from the base element 4 by forming.

In the preferred embodiment, the base element 4 and the cooling elements 8 have a density of at least 98%, in particular at least 98.5%, preferably at least 99% of the full density of the material used.

Full density refers to the density of a cooling device made of the same material by fusion metallurgy, i.e. a component made of a solid material. Solid material here means a metallic material which, with the exception of defects, has no pores, as is usually the case with sintered components.

Provision is made for a cooling fluid, for example water, to flow around the cooling elements 6 so that the heat absorbed by the cooling device 1 is transported away via this cooling fluid. The cooling device 1 is preferably what is known as a pin fin cooling device.

The cooling elements 6 of the embodiment depicted are cylindrical. However, they can also be a different shape, for example frustoconical or generally a cross-section tapering in the direction of a cooling element head 7, for example a frusto-pyramidal cross-section. According to an embodiment, several or all cooling elements 6 in the head region can be mushroom shaped, as indicated by dashed lines in FIG. 6.

The cross section of the cooling elements 6 can be circular, oval, diamond shaped, square, etc.

Furthermore, all cooling elements 6 can be configured identically. However, it is also possible to arrange or combine cooling elements 4 of different shapes on or with a base element 6.

The cooling elements 6 can preferably have a height 8 above the first surface 5 of the base element 4 that is between 2 mm and 20 mm.

In the simplest embodiment of the cooling device 1, all cooling elements 6 of the cooling device 1 have the same height 8 within tolerance limits. However, within the scope of the invention, it is possible for some of the cooling elements 6 to have a lower height than the other cooling elements 6. In this case, the cooling elements 6 with the lower height, i.e. their cooling element head 7, can be (clearly) mushroom shaped, for example.

Furthermore, it can be provided that cooling elements 6 are arranged or formed per dm² of the first surface area 5 between 300 and 1300, in particular between 300 and 1000, for example between 300 and 750. This number in particular has proven to be advantageous with regard to the production of the cooling device 1, i.e. forming the base element 4 into the cooling elements 6, since damage to the cooling elements 6 or incompletely formed cooling elements 6 can thus be avoided or reduced.

As can be seen in particular from FIG. 1, according to one embodiment of the cooling device 1, it can be provided that the rear side 3 of the base element 4 is configured to have a planar surface. However, it is also possible for the rear side 3 to be formed with one or more depressions 9, in which a component 2 is at least partially received. This permits better connection of the component 2 to the cooling device 1. In general, the component 2 can be glued or screwed or soldered or sintered, etc., to the cooling device 1, for example.

The at least one depression 9 can be produced simultaneously with the cooling elements 6 during their production. It is also possible to produce cooling elements 6, whose height 8 is greater than that of the other cooling elements 6, by the at least one recess 9.

As can be seen from FIG. 2, the cooling device 1 can have at least one further structural element 10 on the first surface 5 of the base element 4. In the shape shown, the structural element 10 is a cylinder, but can also have a different cross-sectional area, for example diamond shaped. With the structural element 10, a further surface 11 can be provided on the cooling device 1, which lies above the plane of the cooling elements 6. The structural element 10 can thus have a greater height than the cooling elements 6. However, it is also possible for the at least one structural element 10 to have a lower height or the same height as the cooling elements 6. Furthermore, more than one structural element 10 can be arranged, wherein the plurality of structural elements 10 can be configured identically or differently, e.g. in terms of shape and/or height.

The structural element 10 can be provided, for example, for a screw connection, as stiffeners or as a spacer or as a stop.

The structural element 10 is preferably not mechanically finished, but rather co-pressed or produced by powder metallurgy in net shape or near net shape quality during the pressing of a preform for the production of the cooling device 1. The structural element 10 or the structural elements 10 are therefore preferably formed integrally with the base element 4 and the cooling elements 6.

To produce the cooling device 1, a sintered powder or a powder used in powder metallurgy, in particular a metallic powder, is used. Preferably, a sinter powder with correspondingly good thermal conductivity is used. In particular, a sinter powder based on aluminum or an aluminum alloy or based on copper or a copper alloy or an MMC powder (metal matrix composite) is used.

The cooling device 1 is produced by powder metallurgy according to a powder metallurgy process, i.e. the cooling device 1 is preferably a sintered component. For this purpose, a green compact is manufactured in a corresponding mould (die) from a sintered powder, which can be produced from the individual (metallic) powders by mixing, wherein the powders used can optionally be pre-alloyed. The green compact preferably has a density of at least 80%, in particular between 80% and 96% of the full density of the material.

The green compact can subsequently be dewaxed at customary temperatures and sintered in one, two or more stages and then preferably cooled to room temperature. Sintering can take place at a temperature between 500° C. and 1300° C., for example.

Since these processes and the process parameters used are also known from the prior art, reference to the relevant prior art is made in this regard in order to avoid repetition.

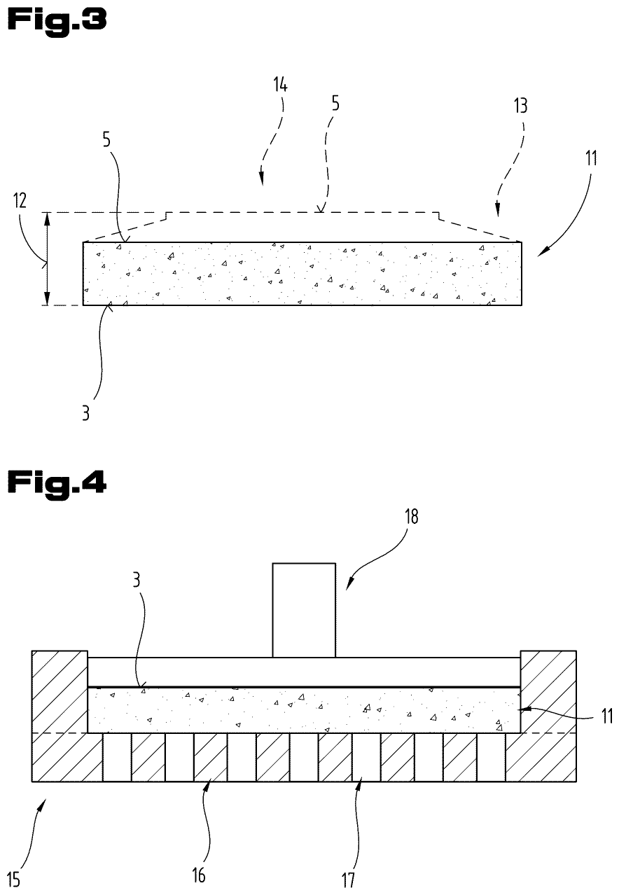

The sintering produces a preform 11 from the green compact, as shown by way of example in FIG. 3. The preform 11 can be configured as a flat plate or plate-shaped so that the rear side 3 and at least a section of the first surface 5 can extend parallel to one another.

According to an embodiment of the method, it can be provided that the first surface 5 of the preform 11, upon which the cooling structure is formed, is produced at least in sections in a curved manner. In general, the preform 11 can be produced at least in sections with a different thickness 12. In particular, the preform 11 can be produced thinner in at least one edge section 13 or in a plurality of edge sections 13 than in a central section 14, as shown by dashed lines in FIG. 3. The central section 14 is the region of the preform 11 with the greatest thickness 12. The thinner edge sections 13 can, for example, be formed circumferentially around the central section 14, i.e. along the entire circumference of the central section 14. The reduction in thickness 12 can be discontinuous and/or ramp-shaped starting from the central portion 14, as is also shown in FIG. 3. Other shapes are also possible.

The reduced thickness 12 in at least one edge portion 13 can also still be present in the finished cooling device 1, as shown in FIG. 2.

Other shapes of the first surface of the preform 11 are possible with regard to improved formability of the preform 11. In this way, first pin fin attachments or cooling element attachments (circular, oval, elliptical, etc.) with a height between 0.1 mm and 2.0 mm can already be preformed. In addition, structures (corrugations, ribs, etc.) can be deliberately introduced into the surface 5 of the preform in order to increase swirling of a cooling fluid, if necessary.

The preform 11 can subsequently be re-compressed. Preferably, however, re-compression takes place at the same time as the forming of the preform 11 into the cooling elements 6.

The forming of the preform 11 takes place in a forming tool 15. For this purpose, the preform 11 is inserted into the forming tool 15 or placed against it. In the simplest case, the forming tool 15 is formed by a perforated plate 16. The perforated plate 16 has recesses 17, in particular apertures, into or through which a part of the material of the preform 11 is pressed, thereby forming the cooling elements 6. The remainder of the material of the preform 11, which is not pressed into or through the forming tool 15, forms the base member 4.

The recesses 17, i.e. their cross section, are correspondingly adapted to the cross section of the cooling elements 6 to be produced.

The forming tool 15 can also look different, i.e. it does not necessarily have to be a simple perforated plate 16. In particular, the forming tool 15 can be configured as a “cup-shaped” die.

In the event that at least one further structural element 10 is present, this can be accounted for by a corresponding recess or a corresponding opening in the forming tool 15.

For forming, a punch 18 can be placed against the rear side 3, of the preform 11, which also forms the rear side 3 of the base element 4 and is pressed onto the preform 11 with a pre-determinable pressure. As a result of the pressure exerted onto the preform 11, material of the preform 11 is pressed into the recesses 17 or apertures of the forming tool 15. Forming can take place at a pressure between 700 MPa and 1600 MPa, for example. Furthermore, forming can take place for up to 10 seconds of time, in particular between 0.1 seconds and 10 seconds. Furthermore, forming preferably takes place at room temperature (20° C.), i.e. cold, or forming can also take place after preheating the preform 11 to a temperature between 50° C. and 300° C., for example between 50° C. and 150° C., and/or in/with a forming tool 15 heated to a temperature between 50° C. and 300° C., for example between 50° C. and 150° C.

After forming, i.e. the forming of the preform 11, the cooling device 1 is calibrated. Calibrating increases the dimensional accuracy of the cooling device 1 at least in sections or in areas. In addition, by calibrating, the pores in the area of the calibrated surface can be closed, such that a denser structure can be achieved. During calibration, the cooling structure, in particular at least some of the cooling elements 6, are thus exposed to pressure on their respective surface(s).

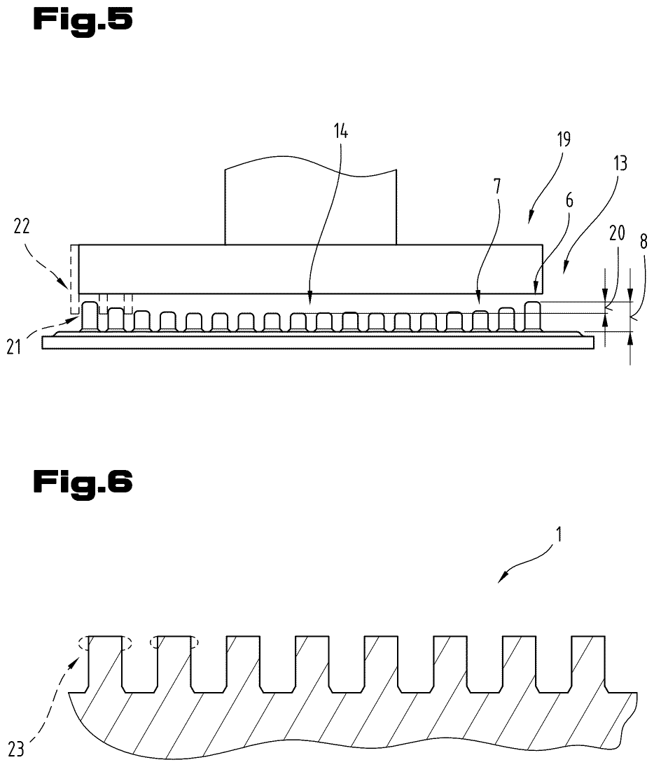

According to a preferred embodiment, a height calibration of the cooling elements 6 can be carried out as shown in FIG. 5. In this case, the cooling element heads 7, can be pressed from above with a calibrating tool 19, which can be plate-shaped or punch-shaped, for example. During this process, the cooling device 1 can be held in a holding element, such as a die. To elucidate the height calibration, the heights 8 of the cooling elements 6 in the edge sections 13 are shown in an exaggeratedly enlarged manner in FIG. 5 so that a clear height difference can be seen. The height deviation can decrease in the direction of the central section 14 of the cooling device 1 until a tolerable tolerance range of the height difference 20 or the heights 8 of the cooling elements 6 is achieved. If part of this height difference 20 is not already taken into account by the shape of the preform 11 (for example by forming regions with different thicknesses 12, following a curve, for example), calibration can be carried out in a correspondingly comprehensive manner. With a preform 11 that already at least partially takes into account a height deviation of the sintered and formed green compact, the work involved in calibration can be reduced.

As shown in the left part of FIG. 5, the calibration tool 19 can also have mold cavities 21 in which the cooling elements 6 are at least partially received during calibration. These mold cavities 21 can be formed as depressions in the calibration tool 19 or by (web-shaped) tool walls 22, for example.

Calibration can take place in one or more stages, optionally with an intermediate relief of the cooling device 1 between the calibration steps.

According to an embodiment, it can also be provided that the height 8 of the cooling elements 6 is adjusted by pressing material from the head region of the cooling elements 6 (the cooling element heads 7) into a region 23 adjacent to or below the head region of the cooling elements 6. This is shown in exaggerated manner in FIG. 6, which shows a portion of a calibrated cooling device 1. A simple plate tool, in particular the aforementioned calibration tool 19, which is pressed against the cooling elements 6, can be used for pressing.

For calibrating or compressing material, it can be advantageous for the cooling elements 6 to have a height difference 20 between a maximum of 0.2 mm and a maximum of 0.4 mm after forming, i.e. to be produced with relatively minor height differences. This can be done with the aforementioned consideration of the shape of the preform 11, for example. The final height tolerance can be achieved more easily in subsequent operation by means of height calibration.

Calibration renders superfluous machining of the cooling elements 6 to reduce the height tolerance of the cooling elements 6. The type of reduction in the height tolerance, can result in partially mushroom-shaped or (slightly) bulged cooling elements 6, which can also be advantageous with regard to the flow of a cooling fluid flowing around the cooling elements 6 and thus the cooling capacity of the cooling device 1. In addition, reducing the height tolerance can reduce or eliminate residual porosity at the upper end of the cooling elements 6.

As mentioned above, the cooling device 1 can also have cooling elements 6 with a different height 8 from one another. In order to be able to carry out height calibration or calibration in this case as well, the calibration tool can be configured in accordance with the desired height profile of the cooling elements 6 in a stepped manner, for example.

A correspondingly configured calibration tool 19 can also be used to form certain shapes of the cooling elements 6. For this purpose, the calibration tool 19 can have a mating contour in order to form the heads of the cooling elements 6 accordingly, for example, i.e. to provide them with a contour or surface design, such as a rounding, a chamfer, etc., or with a depression, a surface roughness that is greater than the roughness after sintering, etc.

In the event that cooling elements 6 of different heights are formed, a stepped calibration tool 19 can also be used.

The method according to the invention can be used to produce a cooling device 1 for cooling components 2, which are provided with a base element 4 having a first surface 5, and with a cooling structure having cooling elements 6, which is arranged on the base element 4 so as to project beyond the first surface 5. At least some of the cooling elements 6 in the head region can have a higher density than the other cooling elements 6 and/or that at least some of the cooling elements 6 in the head region are a different shape to the other cooling elements 6.

The exemplary embodiments show possible embodiments, yet it should be noted at this point that combinations of the individual embodiments with one another are also possible.

For the sake of good order, it should finally be pointed out that the structure of the cooling device 1 or the forming tool 15 is not necessarily shown to scale for better understanding.

Although only a few embodiments of the present invention have been shown and described, it is to be understood that many changes and modifications may be made thereunto without departing from the spirit and scope of the invention.

### LIST OF REFERENCE NUMERALS

1 Cooling device
2 Component
3 Rear side
4 Base element
5 Surface
6 Cooling element
7 Cooling element head
8 Height
9 Depression
10 Structural element
11 Preform
12 Thickness
13 Edge section
14 Central section
15 Forming tool
16 Perforated plate
17 Recess
18 Punch
19 Calibration tool
20 Height difference
21 Mold cavity
22 Tool wall
23 Region

What is claimed is:

1. A method for producing a cooling device (1) comprising the steps of providing a material and forming a cooling structure from the material, wherein a sinter powder is used as the material, from which a green compact is produced by pressing, wherein the green compact is sintered to form a preform (11), and wherein the cooling structure in the form of cooling elements (6) is produced from the preform (11) by forming, for which a part of the preform (11) is pressed through a forming tool (12), and wherein the cooling structure is calibrated after forming.

2. The method according to claim 1, wherein the cooling structure is formed at least in regions by the calibration.

3. The method according to claim 1, wherein the height (8) of the cooling elements (6) is adjusted during calibration by pressing material out of the head region of at least some of the cooling elements (6) into a region (23) adjacent to or below the head region of these cooling elements (6).

4. The method according to claim 1, wherein the cooling structure is produced by using a perforated plate (16) as a forming tool (12) in the form of pin-shaped cooling elements (6).

5. The method according to claim 1, wherein the preform (11) is plate shaped.

6. The method according to claim 1, wherein the preform (11) is produced with different thickness (12) at least in sections.

7. The method according to claim 5, wherein the preform (11) is produced more thinly in its edge sections (13) than in a central section (14).

8. The method according to claim 1, wherein the preform (11) is re-compressed and wherein the cooling structure is partially formed during re-compression.

9. A cooling device (1) for cooling components (2) comprising a base element (4) having a first surface (5), and with a cooling structure having cooling elements (6) and being arranged on the base element (4) so as to project beyond the first surface (5), wherein the base element (4) and the cooling elements (6) are composed of a sintered material, and wherein the cooling elements (6) are produced from the material of the base element (4) by forming, and wherein at least some of the cooling elements (6) in the head region have a higher density than the other cooling elements (6), and/or wherein at least some of the cooling elements (6) in the head region are a different shape to the other cooling elements (6).

10. The cooling device (1) according to claim 9, wherein at least some of the cooling elements (6) are mushroom shaped.

11. The cooling device (1) according to claim 9, wherein the base element (4), and the cooling elements (6) have a density of at least 98% of the full density of the material used.

12. The cooling device (1) according to claim 9, wherein the cooling elements (6) have a height (8) above the first surface (5) of the base element (4) that is between 2 mm and 20 mm.

13. The cooling device (1) according to claim 9, wherein a rear side (3) of the base element (4) is configured to have a planar surface.

14. The cooling device (1) according to claim 9, wherein at least one further structural element (10) is arranged on the first surface (5) of the base element (4), which protrudes beyond the cooling elements (6) in the direction of the height (8) and which is produced in net-shape or near net-shape quality.
